(19) United States
(12) Patent Application Publication
(10) Pub. No.: US 2026/0066003 A1
(43) Pub. Date: Mar. 5, 2026

(54) SSD WITH REDUCED READ LATENCY IN LAST WRITTEN WORDLINE OF OPEN BLOCK

(71) Applicant: Microchip Technology Incorporated, Chandler, AZ (US)

(72) Inventors: Salvatrice Scommegna, Cornate D'Adda (IT); Pitamber Shukla, San Jose, CA (US); Antonio Aldarese, Vimercate (IT); Michele Cirella, Castelmassa (IT)

(73) Assignee: Microchip Technology Incorporated, Chandler, AZ (US)

(21) Appl. No.: 19/247,349

(22) Filed: Jun. 24, 2025

Related U.S. Application Data
(60) Provisional application No. 63/687,636, filed on Aug. 27, 2024.

(51) Int. Cl. G11C 16/26; G11C 16/08; G11C 16/24; G11C 16/34

(52) U.S. Cl. CPC G11C 16/26; G11C 16/08; G11C 16/24; G11C 16/3495

(57) ABSTRACT

A solid-state drive with improved read latency in a last-written wordline of an open, or partially programmed, block, and a method of improving read latency in a last-written wordline of an open block in a solid-state drive. The solid-state drive includes a NAND-based or other non-volatile memory media. The media includes the open, or partially programmed, block, and a controller. The controller receives a read request that includes the last-written wordline of the open block. The controller performs a read operation to fulfill the read request, including reading the last-written wordline with a reduced bitline bias, which raises a threshold voltage to compensate for an increase in string current. The reduced bitline bias is lower than a normal bitline bias used to read a non-last-written wordline.

### RELATED APPLICATIONS

The present U.S. non-provisional patent application is related to and claims priority benefit of an earlier-filed U.S. provisional patent application titled “SSD with Reduced Read Latency in Last Written Wordline of Open Block,” Ser. No. 63/687,636, filed Aug. 27, 2024. The entire content of the identified earlier-filed application is incorporated by reference as if fully set forth herein.

### FIELD

The present disclosure relates to solid-state drives and methods of implementing them, and more particularly, the various examples described herein concern a solid-state drive with improved read latency in a last-written wordline of an open block, and a method of improving read latency in a last-written wordline of an open block in a solid-state drive.

### BACKGROUND

Solid-state drives (SSD) use non-volatile memory (NVM) media (e.g., NAND-based memory media) for data storage, and typically include application-specific integrated circuit (ASIC) controllers for managing read, write, and other operations. SSDs are typically used in enterprise computing data center solutions (DCS) and certain high-performance computing (HPC) applications, including artificial intelligence (AI). It is generally desirable to improve the performance and reduce the cost of SSDs, but it can be difficult to do so.

This background discussion is intended to provide related information, and is not necessarily prior art.

### SUMMARY

Examples provide an SSD with improved read latency in a last-written wordline (WL) of an open (i.e., partially programmed) block, and a method of improving read latency in a last-written WL of an open block in an SSD. Broadly, examples read the last-written WL with a reduced bitline (BL) bias, which decreases the threshold voltage (Vt) to compensate for the increased string current (Icell). Reducing the BL bias reduces the Icell so that the last-written WL can be correctly read. The BL bias for the last-written WL is reduced relative to the normal BL bias of the other, non-last-written WLs. This reduces the number of read errors, which reduces the number of read-recovery scheme activations, which reduces the read latency and thereby advantageously improves the read latency for open blocks.

In an example, an SSD with reduced read latency in a last-written WL of a partially programmed block of an NVM media may include the NVM media and a controller. The NVM media may contain the partially programmed block. The controller may be configured to perform a plurality of operations including the following. The controller may receive a read request that includes the last-written WL of the partially programmed block, and the controller may perform a read operation to fulfill the read request. The read operation may include reading a plurality of non-last-written WLs with a normal BL bias, and reading the last-written WL with a reduced BL bias which raises a Vt to compensate for an increase in Icell, wherein the reduced BL bias is lower than the normal BL bias used to read the plurality of non-last-written WLs.

The preceding example may further include any one or more of the following features. The reduced BL bias may be between five (5) and fifteen (15) percent lower than the normal BL bias. The reduced BL bias may be based on a plurality of relevant factors including a temperature, a number of program/erase (P/E) cycles, an amount of the partially programmed block that is programmed, and a type of the NVM media. The controller may find the reduced BL bias in a look-up table that takes into account the plurality of relevant factors, or the controller may calculate the reduced BL bias using a formula that takes into account the plurality of relevant factors. The NVM media may be a NAND-based memory media. The controller may apply an internal NAND voltage to pre-charge the normal BL bias in order to provide the reduced WL bias. The controller may change an internal NAND voltage during the read operation in order to provide the reduced BL bias.

In another example, a method of reducing a read latency in a last-written WL of a partially programmed block of an NVM media in an SSD may include the operations set forth below. The SSD may include the NVM media in which the partially programmed block is located and a controller configured to perform a plurality of operations. A read request may be received that includes the last-written WL of the partially programmed block. A read operation may be performed with the controller to fulfill the read request, including reading a plurality of non-last-written WLs with a normal BL bias, and reading the last-written WL with a reduced BL bias which raises a Vt to compensate for an increase in Icell, wherein the reduced BL bias is lower than the normal BL bias used to read the plurality of non-last-written WLs.

The preceding example may further include any one or more of the following features. The reduced BL bias may be between five (5) and fifteen (15) percent lower than the normal BL bias. The reduced BL bias may be based on a plurality of relevant factors including a temperature, a number of P/E cycles, an amount of the partially programmed block that is programmed, and a type of the NVM media. The controller may find the reduced BL bias in a look-up table that takes into account the plurality of relevant factors, or the controller may calculate the reduced BL bias using a formula that takes into account the plurality of relevant factors. The NVM media may be a NAND-based memory media. The controller may apply an internal NAND voltage to pre-charge the normal BL bias in order to provide the reduced BL bias. The controller may change an internal NAND voltage during the read operation in order to provide the reduced BL bias.

In another example, a method of reducing a read latency in a last-written WL of a partially programmed block of a NAND-based NVM media in an SSD may include the operations set forth below. The SSD may include the NAND-based NVM media in which the partially programmed block is located and a controller configured to perform a plurality of operations. A read request may be received from a host for data stored in the NAND-based NVM media, the read request may include the last-written WL of the partially programmed block. A read operation may be performed by the controller to fulfill the read request, including reading a plurality of non-last-written WLs with a normal BL bias, determining a reduced bitline bias based on a plurality of relevant factors, wherein the reduced bitline bias is between five (5) and fifteen (15) percent lower than the normal bitline bias, and reading the last-written WL with the reduced BL bias which raises a Vt to compensate for an increase in Icell by lowering the string current.

The preceding example may further include any one or more of the following features. The plurality of relevant factors may include a temperature, a number of P/E cycles, an amount of the partially programmed block that is programmed, and a type of the NAND-based NVM media. The controller may determine the reduced BL bias by finding the reduced BL bias in a look-up table that takes into account the plurality of relevant factors, or by calculating the reduced BL bias using a formula that takes into account the plurality of relevant factors. The controller may apply an internal NAND voltage to pre-charge the normal BL bias in order to provide the reduced BL bias. The controller may change an internal NAND voltage during the read operation in order to provide the reduced BL bias.

This summary is not intended to identify essential features of the examples, and is not intended to be used to limit the scope of the claims. These and other aspects of the present examples are described below in greater detail.

### DRAWINGS

Examples are described in detail below with reference to the attached drawing figures, wherein:

FIG. 1 is a high-level block diagram of components and operations of an example of an SSD with reduced read latency in a last-written WL of an open block; and

FIG. 2 is a high-level schematic depiction of an example memory array of WLs and BLs, showing cells in WLs in an open block;

FIG. 3 is a block diagram of a cell in an “erase”state;

FIG. 4 is a block diagram of a cell in a “program”state;

FIG. 5 is a graph of single-level cell (SLC) Vt distribution for cells in erase and program states;

FIG. 6 is a graph of an Isense current versus a voltage applied on the WL, wherein Isense is the current at which log(Icell) crosses Vt;

FIG. 7 is a graph of the SLC Vt distribution for cells in erase and program states in an open block;

FIG. 8 is a graph of Isense versus the voltage applied on the WL for partially programmed blocks; and

FIG. 9 is a flowchart of operations in an example of a method of implementing reduced read latency in a last-written WL of an open block in an SSD.

The figures are not intended to limit the examples to the specific details depict. The drawings are not necessarily to scale.

### DETAILED DESCRIPTION

In the following detailed description, reference is made to the accompanying drawings, which form a part hereof and in which are shown, by way of illustration, specific examples in which the present disclosure may be practiced. These examples are described in sufficient detail to enable a person of ordinary skill in the art to practice the present disclosure. However, other examples may be utilized, and structural, material, procedural, operational, and other changes may be made without departing from the scope of the disclosure. Unless clearly understood or expressly identified otherwise, structures, materials, procedures, operations, and other aspects described in the context of one example may be incorporated into other examples.

The illustrations presented herein are not meant to be actual views of any particular method, system, device, or structure, but are merely idealized representations that are employed to describe the examples of the present disclosure. The drawings presented herein are not necessarily drawn to scale. Similar structures or components in the various drawings may retain the same or similar numbering for the convenience of the reader; however, any similarity in numbering does not necessarily mean that the structures or components are necessarily identical in size, composition, configuration, or any other property.

Terms of relative location and direction (e.g., above, below, left, right, upper, lower) may be used to facilitate the present descriptions of examples with reference to the figures, but unless clearly understood or expressly identified otherwise, these terms are not meant to be limiting with regard to location, direction, or overall orientation, and may, for example, change as a result of a change in overall orientation.

It will be readily understood that the components of the examples as generally described herein and illustrated in the drawings could be arranged and designed in a wide variety of different configurations. Thus, the following description of various examples is not intended to limit the scope of the present disclosure but is merely representative of various examples.

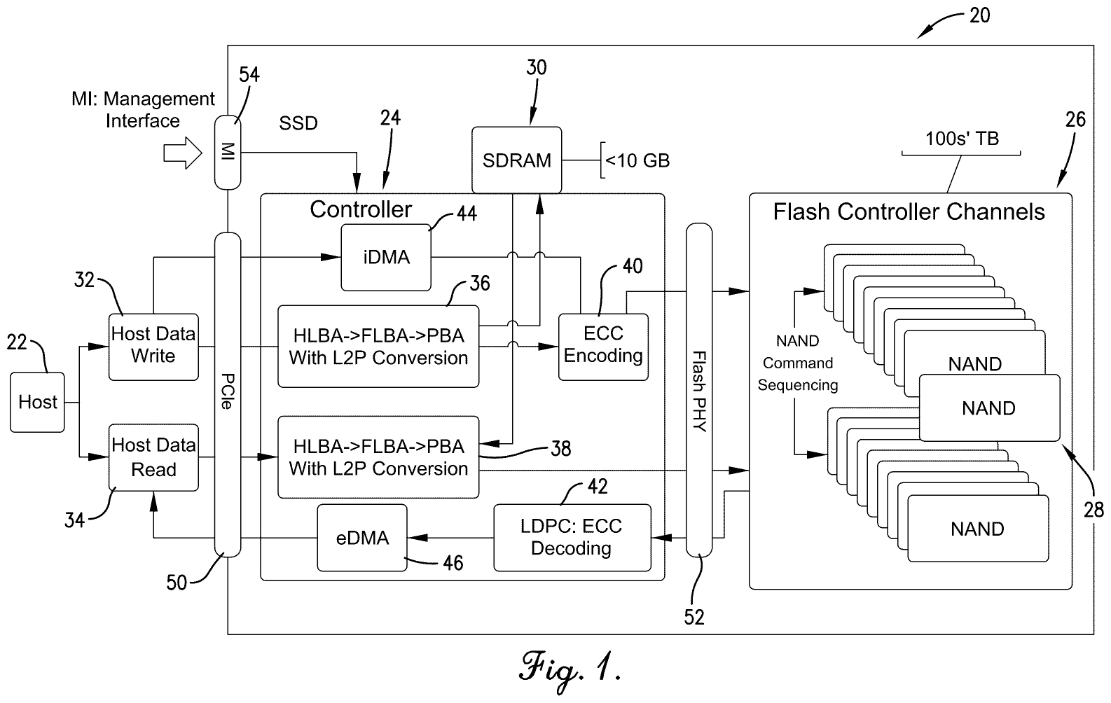

Referring to FIG. 1, a high-level block diagram of components, operations, and an operating context of an example SSD 20 is shown including a host 22 configured to write and read data to and from the SSD 20; a controller 24 configured to control various SSD operations, such as those discussed below; and an NVM media 26, such as a NAND-based memory media in the form of a plurality of NAND dies 28. Each NAND die may include one or more planes, each plane may include multiple blocks, each block may include multiple pages, and each page may include multiple cells. Each block may be arranged as an array of WLs and BLs, with each WL representing a page. Although described herein with regard to NAND-based memory media, examples may employ substantially any suitable memory array technology, such as NOR-based memory media and dynamic random access memory (DRAM).

Generally, the SSD 20 may operate as follows. A write or read request may be received from the host 22 via a peripheral component interconnect express (PCIe) or other suitable interface 50. PCIe is a standardized interface for motherboard components. The controller 24 may use logical block addresses (LBAs) and physical block addresses (PBAs) to facilitate access for data storage in and retrieval from the NVM 26. LBAs are an abstraction to allow the operating system to interact with the NVM 26, and PBAs represent the actual hardware locations within the NVM 26. To facilitate interacting with the NVM 26, the controller 24 may create an entry or record that assigns an LBA to a PBA. To keep track of all such LBA-to-PBA assignments, the controller 24 may use a logical-to-physical (L2P) mapping table. The L2P table may be uploaded to synchronous dynamic random access memory (SDRAM) 30 so that it can be more quickly accessed and updated by the controller 24. When a write or read data request 32, 34 is received from the host 22, the controller 24 performs a reference operation 36, 38 to the L2P mapping table to determine the PBA within the NVM corresponding to a desired LBA. Once the PBA is determined, the controller 24 accesses the appropriate NVM cell to write or read the data. Access to the NVM 26 may be via a flash physical (PHY) or other suitable interface 52. The controller 24 may employ an error correction code (ECC) operation 40, 42 during encoding and decoding of data to detect and correct errors and enhance data integrity. Additionally, the SSD 20 may support a direct memory access (DMA) operation 44, 46, enabling data to be written from the host 22 directly to the NVM 26 and read from the NVM 26 directly to the host 22.

In the normal operation of an SSD, such as the SSD 20 described above, some NAND blocks may be left “open,” or partially programmed, i.e., some WLs contain data and some WLs are in the erase state. Open blocks can be potentially problematic because they are associated with reliability and read latency issues, but it is not always possible to ensure that blocks are fully programmed. For example, when NANDs are used to store important information during a power outage, the controller 24 may not have sufficient time or freedom to fully program the NAND blocks. One problem with an open NAND block is that the Icell of the last-written WL appears higher relative to other WLs whose adjacent, or neighboring, WLs are both in the programmed state. The last-written WL has one adjacent WL in an erase state and also the fraction of the block in the erase state which will impact the positioning of Vt of the last-written WL relative to the other, non-last-written WLs in the open block. The Vt appears lower for the last-written WL so the Icells are different, which causes a read mismatch between the last-written WL and the other WLs in the block. This condition is even more pronounced in NANDs that have more stacking of layers and less spacing between layers, which results in a significant increase in neighboring WL interference. If the number of read errors is too high, the controller 24 may need to use a read-recovery scheme, such as BRP, which may cause a significant read latency problem.

Examples provide the SSD 20 with improved read latency in a last-written WL of an open block, and a method of improving read latency in a last-written WL of an open block in an SSD 20. Broadly, the controller 24 knows which WL is the last written WL, and examples read the last-written WL with a reduced BL bias, which reduces Vt to compensate for the increased Icell. Reducing the BL bias reduces Icell so that the last-written WL can be correctly read. The BL bias for the last-written WL is reduced relative to the normal, or default, BL bias of the plurality of other, non-last-written WLs. This reduces the number of read errors, which reduces the number of read-recovery scheme (e.g., BRP) activations, which reduces the read latency, and thereby advantageously improves the read latency for open blocks. The size of the relative reduction in the BL bias may at least partially depend on a plurality of factors, which may include the temperature, the number of P/E cycles, the amount of the block that is in the programmed (as opposed to the erase) condition, and the type of NAND or other NVM media. The controller 24 may determine the appropriate BL bias by finding it in a look-up table or by calculating it using a formula that take into account the plurality of factors, the details of which may depend at least partially on the particular system or the particular application. In general, the BL bias for the last written WL may be approximately between five (5) and fifteen (15) percent lower than the normal BL bias. The controller's ability to change the BL bias may be accomplished through a suitable mode or feature, which may be included by, e.g., the manufacturers of the NVM media 26.

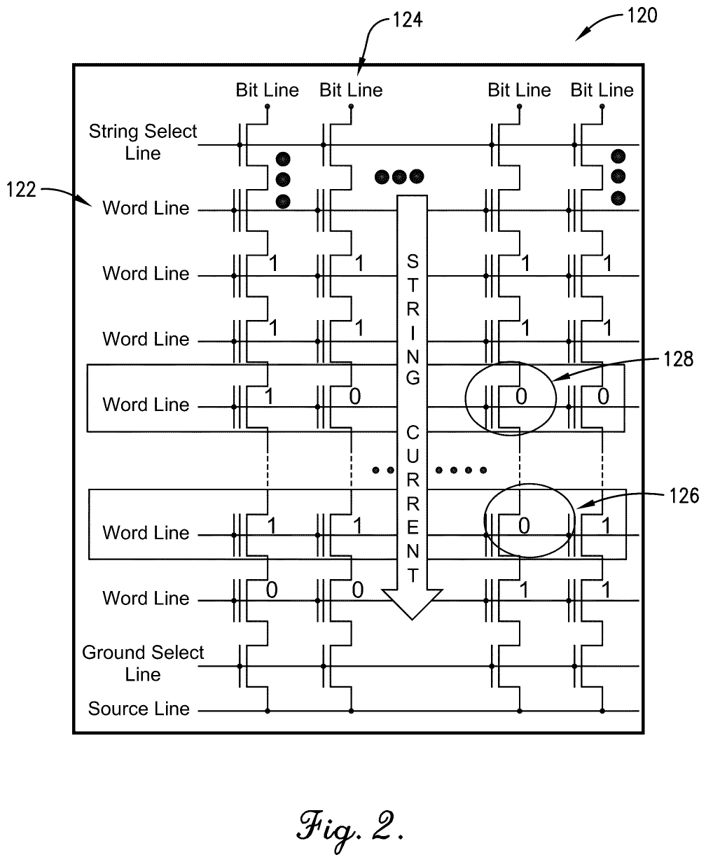

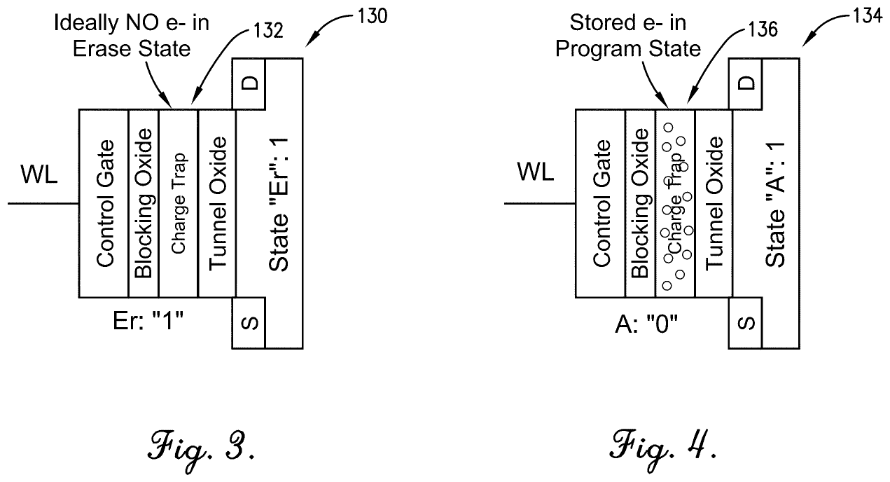

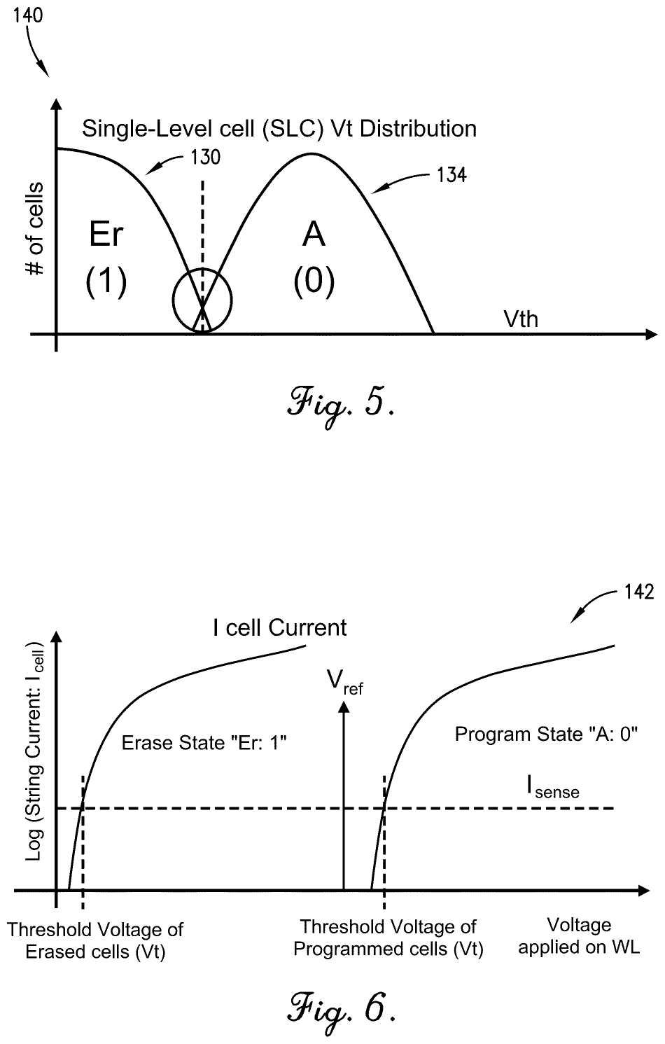

Referring to FIG. 2, an example memory array 120 of WLs 122 and BLs 124 is shown, including a plurality of non-last-written WLs 126 (i.e., a WL with programmed neighbors) and a last-written WL 128 (i.e., a WL with an unprogrammed neighbor). As seen in FIGS. 3 and 4, a first WL cell 130 is shown in an “erase” state, Er:1, in which there ideally are no electrons in the charge trap 132, and a second WL cell 134 is shown in a “program” state, A:0, in which there are electrons stored in the charge trap 136. As seen in FIG. 5, a graph 140 of single-level cell (SLC) Vt distribution for Er:1 cells 130 and A:0 cells 134 is shown. Relatedly, as seen in FIG. 6, a graph 142 of Isense versus the voltage applied on the WL is shown. Isense is the current at the point at which log(Icell) crosses Vt. During a read operation, if the desired Isense is reached with Vt less than Vref, then the cell is in the erase state, Er: 1, and if it is reached with Vt greater than a reference voltage (Vref), then the cell is in the program state A:0.

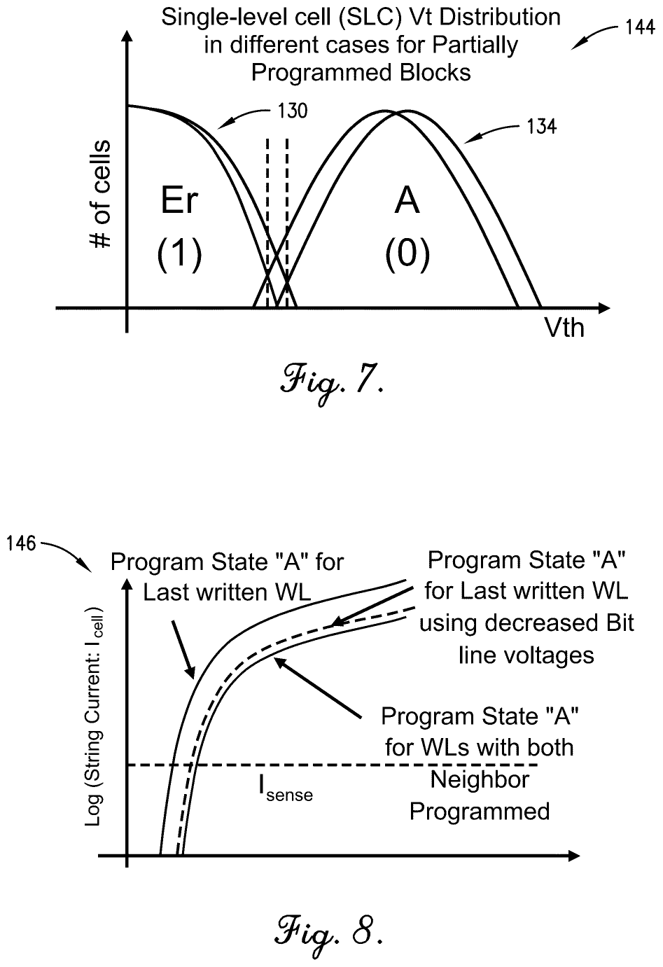

As seen in FIG. 7, a graph 144 of the SLC Vt distribution for Er:1 cells 130 and A:0 cells 134 for partially programmed blocks is shown. Relatedly, as seen in FIG. 8, a graph 142 of Isense versus the voltage applied on the WL for partially programmed blocks is shown, in which the Vt for A:0 in a WL with both neighboring WLs programmed is higher than the Vt for A:0 in the last-written WL in a partially open block, i.e., the Vt appear lower in for the last-written WL. Examples reduce the BL bias when reading the last-written WL, which raises the Vt and thereby reduces read errors and avoids a read latency issue for the partially programmed lock.

In operation, the controller 24 of the SSD 20 may be configured to receive a read request from the host 22 for data that includes the last-written WL of a partially programmed block of the NAND-based or other NVM media 26. The controller 24 of the SSD 20 may also be configured to read the last-written WL with a reduced BL bias, which raises Vt to compensate for an increase in Icell by reducing Icell so that the last-written WL can be more correctly read. The reduced BL bias is lower than the normal BL bias used to read the plurality of other, non-last-written WLs (i.e., WLs with programmed neighbors). Reducing the BL bias may be accomplished by changing the internal voltages that are internally generated by the NANDs to pre-charge the BL biases during a read operation, or by applying an internal NAND voltage.

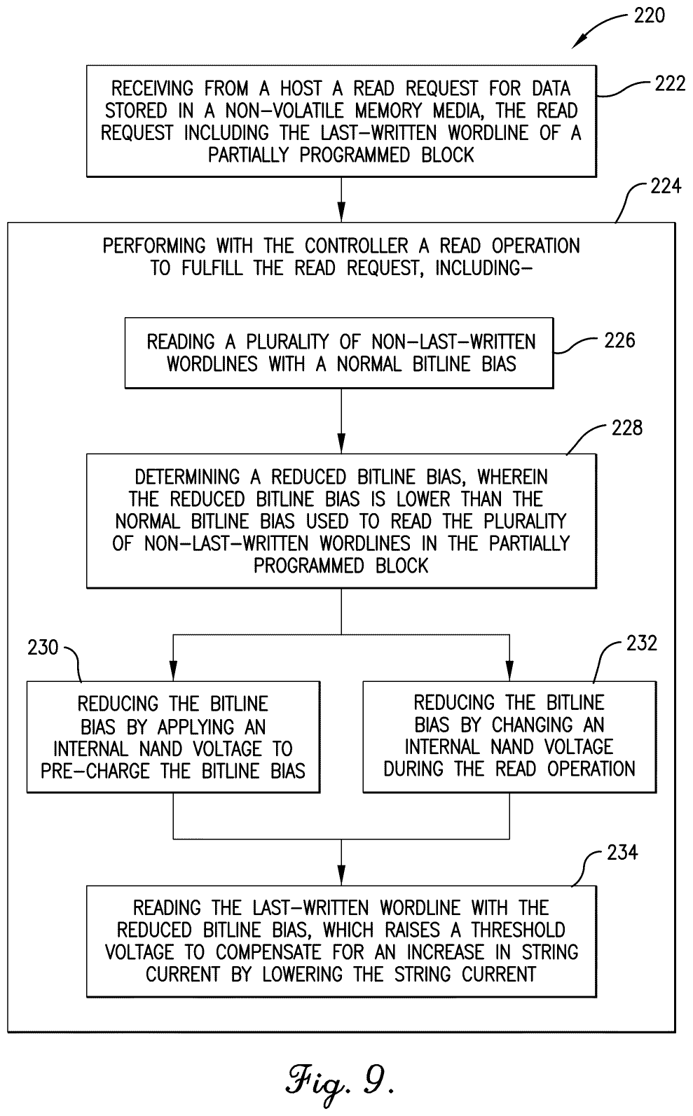

Referring to FIG. 9 an example of a method 220 of reducing a read latency in a last-written WL of an open, or partially programmed, NAND-based or other NVM media block in an SSD may include the operations set forth below. The SSD may be the SSD 20 described above which includes the following: 1) the controller 24 controller configured to perform a plurality of operations, and 2) the NAND-based or other NVM media 26 in which the open block is located.

A read request may be received from a host 22 for data stored in the NVM media 26, and the read request may include the last-written WL of the partially programmed block, as shown in 222. A read operation may be performed with the controller 24 to fulfill the read request, as shown in 224, including the following operations. A plurality of non-last-written WLs may be read with a normal BL bias, as shown in 226.

The controller may determine a reduced BL bias, as shown in 228. The size of the relative reduction in the BL bias may at least partially depend on a plurality of factors, which may include the temperature, the number of P/E cycles, the amount of the block that is in the programmed (as opposed to the erase) condition, and the type of NAND or other NVM media. The controller 24 may determine the appropriate BL bias by finding it in a look-up table or by calculating it using a formula that takes into account the plurality of factors, the details of which may depend at least partially on the particular system or the particular application. In general, the BL bias for the last written WL may be approximately between five (5) and fifteen (15) percent lower than the normal BL bias.

An internal NAND voltage may be applied to pre-charge the normal BL bias in order to provide the reduced BL bias, as shown in 230, or an internal NAND voltage may be changed during the read operation in order to provide the reduced BL bias, as shown in 232. The last-written WL may be read with the reduced BL bias, as shown in 234, which raises Vt to compensate for an increase in Icell by reducing Icell, wherein the reduced BL bias is lower than the normal BL bias used to read the plurality of non-last-written WLs in the partially programmed block. Additional operations may be performed as desired.

While the present disclosure has been described herein with respect to certain illustrated examples, those of ordinary skill in the art will recognize and appreciate that the present disclosure is not so limited. Rather, many additions, deletions, and modifications to the illustrated and described examples may be made without departing from the scope of the disclosure as hereinafter claimed along with their legal equivalents. In addition, features from one example may be combined with features of another example while still being encompassed within the scope of the disclosure as contemplated by the inventors.

1. A solid-state drive with reduced read latency in a last-written wordline of a partially programmed block of a non-volatile memory media, the solid-state drive comprising:
the non-volatile memory media in which the partially programmed block is located; and
a controller configured to configured to perform a plurality of operations including—
receiving a read request that includes the last-written wordline of the partially programmed block; and
performing a read operation to fulfill the read request, including—
reading a plurality of non-last-written wordlines with a normal bitline bias, and
reading the last-written wordline with a reduced bitline bias which raises a threshold voltage to compensate for an increase in string current, wherein the reduced bitline bias is lower than the normal bitline bias used to read the plurality of non-last-written wordlines in the partially programmed block.

2. The solid-state drive of claim 1, wherein the reduced bitline bias is between five (5) and fifteen (15) percent lower than the normal bitline bias.

3. The solid-state drive of claim 2, wherein the reduced bitline bias is based on a plurality of relevant factors including a temperature, a number of program/erase cycles, an amount of the partially programmed block that is programmed, and a type of the non-volatile memory media.

4. The solid-state drive of claim 3, wherein the controller is configured to find the reduced bitline bias in a look-up table that takes into account the plurality of relevant factors.

5. The solid-state drive of claim 3, wherein the controller is configured to calculate the reduced bitline bias using a formula that takes into account the plurality of relevant factors.

6. The solid-state drive of claim 3, wherein the non-volatile memory media is a NAND-based memory media.

7. The solid-state drive of claim 6, wherein the controller is configured to apply an internal NAND voltage to pre-charge the normal bitline bias in order to provide the reduced bitline bias.

8. The solid-state drive of claim 6, wherein the controller is configured to change an internal NAND voltage during the read operation in order to provide the reduced bitline bias.

9. The solid-state drive of claim 1, wherein the non-volatile memory media is a NAND-based memory media.

10. The solid-state drive of claim 9, wherein the controller is configured to apply an internal NAND voltage to pre-charge the normal bitline bias in order to provide the reduced bitline bias.

11. The solid-state drive of claim 9, wherein the controller is configured to change an internal NAND voltage during the read operation in order to provide the reduced bitline bias.

12. The solid-state drive of claim 1, wherein the reduced bitline bias is based on a plurality of relevant factors including a temperature, a number of program/erase cycles, an amount of the partially programmed block that is programmed, and a type of the non-volatile memory media, and
wherein the controller is configured to: find the reduced bitline bias in a look-up table that takes into account the plurality of relevant factors, or calculate the reduced bitline bias using a formula that takes into account the plurality of relevant factors.

13. A method of reducing a read latency in a last-written wordline of a partially programmed block of a non-volatile memory media in a solid-state drive, the solid-state drive including the non-volatile memory media in which the partially programmed block is located, the method comprising—
receiving a read request that includes the last-written wordline of the partially programmed block; and
performing with a controller a read operation to fulfill the read request, including—
reading a plurality of non-last-written wordlines with a normal bitline bias, and
reading the last-written wordline with a reduced bitline bias which raises a threshold voltage to compensate for an increase in string current, wherein the reduced bitline bias is lower than the normal bitline bias used to read the plurality of non-last-written wordlines in the partially programmed block.

14. The method of claim 13, wherein the reduced bitline bias is between five (5) and fifteen (15) percent lower than the normal bitline bias.

15. The method of claim 14, wherein the reduced bitline bias is based on a plurality of relevant factors including a temperature, a number of program/erase cycles, an amount of the partially programmed block that is programmed, and a type of the non-volatile memory media.

16. The method of claim 15, wherein the step of performing the read operation with the controller includes finding the reduced bitline bias in a look-up table that takes into account the plurality of relevant factors.

17. The method of claim 15, wherein the step of performing the read operation with the controller includes calculating the reduced bitline bias using a formula that takes into account the plurality of relevant factors.

18. The method of claim 13, wherein the non-volatile memory media is a NAND-based memory media.

19. The method of claim 18, wherein the step of performing the read operation with the controller includes applying an internal NAND voltage to pre-charge the normal bitline bias in order to provide the reduced bitline bias.

20. The method of claim 18, wherein the step of performing the read operation with the controller includes changes an internal NAND voltage during the read operation in order to provide the reduced bitline bias.
